(19) United States
(12) Patent Application Publication
(10) Pub. No.: US 2025/0214116 A1
(43) Pub. Date: Jul. 3, 2025

(54) SUPPORT MECHANISM FOR ROLL CLEANING MEMBER AND CLEANING DEVICE

(71) Applicant: EBARA CORPORATION, Tokyo (JP)

(72) Inventor: Kenya SUMIDA, Tokyo (JP)

(73) Assignee: EBARA CORPORATION, Tokyo (JP)

(21) Appl. No.: 18/990,932

(22) Filed: Dec. 20, 2024

(30) Foreign Application Priority Data
Dec. 28, 2023 (JP) 2023-223205

(51) Int. Cl. B08B 3/02; B08B 1/52

(52) U.S. Cl. CPC B08B 3/02; B08B 1/52

(57) ABSTRACT

A support mechanism for a roll cleaning member includes: a nozzle body that has a pipe connection port to which a cleaning solution supply pipe is connected and a discharge port from which a cleaning solution is discharged; a cover that is engaged with the roll cleaning member and rotates together with the roll cleaning member; and a bearing that is housed between the nozzle body and the cover. A backflow prevention wall extending in a radial direction with respect to a rotation axis of the roll cleaning member is provided in at least one of the nozzle body and the cover.

### CROSS-REFERENCE TO RELATED APPLICATIONS

This application claims the benefit of Japanese Priority Patent Application JP 2023-223205 filed on Dec. 28, 2023, the entire contents of which are incorporated herein by reference.

### FIELD

The present invention relates to a support mechanism for a roll cleaning member and a cleaning device.

### BACKGROUND AND SUMMARY

Hitherto, it has been known to supply a cleaning solution to the inside of a roll cleaning member for cleaning of a substrate and self-cleaning of the roll cleaning member, and a support mechanism for the roll cleaning member for this purpose is disclosed in JP 3853130 B2 and JP 2020-96087 A.

It is required to increase a supply flow rate of the cleaning solution in order to improve performance in the cleaning of the substrate and the self-cleaning of the roll cleaning member. However, at this time, a part of the cleaning solution discharged from the support mechanism for the roll cleaning member is not supplied to the inside of the roll cleaning member, but leaks to a mechanism side, which is problematic.

It is desirable to provide a support mechanism for a roll cleaning member and a cleaning device capable of reducing an amount of cleaning solution leaking to a mechanism side.

A support mechanism for a roll cleaning member according to an aspect of the present technology includes:

a nozzle body that has a pipe connection port to which a cleaning solution supply pipe is connected and a discharge port from which a cleaning solution is discharged;

a cover that is engaged with the roll cleaning member and rotates together with the roll cleaning member; and

a bearing that is housed between the nozzle body and the cover,

in which a backflow prevention wall extending in a radial direction with respect to a rotation axis of the roll cleaning member is provided in at least one of the nozzle body and the cover.

A cleaning device according to an aspect of the present technology includes:

a roll cleaning member; and

a support mechanism for the roll cleaning member, in which

the support mechanism has:

a nozzle body that has a pipe connection port to which a cleaning solution supply pipe is connected and a discharge port from which a cleaning solution is discharged;

a cover that is engaged with a roll cleaning member and rotates together with the roll cleaning member; and

a bearing that is housed between the nozzle body and the cover, and

a backflow prevention wall extending in a radial direction with respect to a rotation axis of the roll cleaning member is provided in at least one of the nozzle body and the cover.

### BRIEF DESCRIPTION OF DRAWINGS

FIG. 1 is a perspective view illustrating a schematic configuration of a cleaning device according to an embodiment.

FIG. 2 is a perspective view of a support mechanism for a roll cleaning member in the cleaning device illustrated in FIG. 1 when viewed from a side opposite to the roll cleaning member.

FIG. 3 is a perspective view of a longitudinal cross section of the support mechanism for the roll cleaning member illustrated in FIG. 2 when viewed from the side opposite to the roll cleaning member.

FIG. 4 is a perspective view of the longitudinal cross section of the support mechanism for the roll cleaning member illustrated in FIG. 2 when viewed from a roll cleaning member side.

FIG. 5 is a view illustrating a longitudinal cross section of the support mechanism for the roll cleaning member illustrated in FIG. 2.

FIG. 6 is a perspective view illustrating a configuration of a nozzle body of the support mechanism for the roll cleaning member illustrated in FIG. 2.

FIG. 7 is an enlarged view of the vicinity of a distal end part of the nozzle body in the support mechanism for the roll cleaning member illustrated in FIG. 2.

FIG. 8 is an enlarged view of the vicinity of a distal end part of a nozzle body in a support mechanism for a roll cleaning member according to a first modified example.

FIG. 9 is an enlarged view of the vicinity of a distal end part of a nozzle body in a support mechanism for a roll cleaning member according to a second modified example.

FIG. 10 is an enlarged view of the vicinity of a distal end part of a nozzle body in a support mechanism for a roll cleaning member according to a comparative example.

### DETAILED DESCRIPTION OF NON-LIMITING EXAMPLE EMBODIMENTS

A support mechanism for a roll cleaning member according to a first aspect of an embodiment includes:

a nozzle body that has a pipe connection port to which a cleaning solution supply pipe is connected and a discharge port from which a cleaning solution is discharged;

a cover that is engaged with a roll cleaning member and rotates together with the roll cleaning member; and a bearing that is housed between the nozzle body and the cover,

in which a backflow prevention wall extending in a radial direction with respect to a rotation axis of the roll cleaning member is provided in at least one of the nozzle body and the cover.

According to such an aspect, the backflow prevention wall that is provided in a direction of a flow (backflow) of the cleaning solution discharged from the discharge port and pushed back by a back pressure inside the roll cleaning member hinders the flow, and thus, it is possible to reduce an amount of the cleaning solution leaking to the mechanism side. In addition, since particles generated in the bearing are hindered by the backflow prevention wall, it is possible to prevent the particles from being mixed into the roll cleaning member.

A support mechanism for a roll cleaning member according to a second aspect of the embodiment is the support mechanism for a roll cleaning member according to the first aspect, in which

the cover has an extending part extending toward the roll cleaning member from the discharge port of the nozzle body, and

the backflow prevention wall is provided so as to extend inward in the radial direction from the extending part.

According to such an aspect, it is possible to improve rigidity of the cover.

A support mechanism for a roll cleaning member according to a third aspect of the embodiment is the support mechanism for a roll cleaning member according to the second aspect, in which

a gap in the radial direction between an inner circumference of the discharge port and a distal end of the backflow prevention wall is smaller than a gap in a direction of the rotation axis between an end surface of the nozzle body on which the discharge port is formed and a side surface of the backflow prevention wall when viewed in a cross section including the rotation axis.

According to such an aspect, the gap in the radial direction between the inner circumference of the discharge port and the distal end of the backflow prevention wall is small, and thus, it is possible to reduce an amount of the cleaning solution leaking to the mechanism side.

A support mechanism for a roll cleaning member according to a fourth aspect of the embodiment is the support mechanism for a roll cleaning member according to the first aspect, in which

the nozzle body has an extending part extending toward the roll cleaning member from the cover,

the discharge port is formed at a distal end of the extending part, and

the backflow prevention wall is provided so as to extend outward in the radial direction from the extending part.

A support mechanism for a roll cleaning member according to a fifth aspect of the embodiment is the support mechanism for a roll cleaning member according to any one of the first to fourth aspects, in which

the nozzle body further has a second pipe connection port to which a second cleaning solution supply pipe is connected.

According to such an aspect, it is possible to increase a supply flow rate of the cleaning solution to the inside of the roll cleaning member without increasing a pipe diameter of the cleaning solution supply pipe or increasing a size of the bearing.

A cleaning device according to a sixth aspect of the embodiment includes:

a roll cleaning member; and

the support mechanism for a roll cleaning member according to any one of the first to fifth aspects.

Hereinafter, specific examples of embodiments will be described in detail with reference to the accompanying drawings. In the following description and the drawings used in the following description, the same reference numerals are used for parts that can be configured identically, and redundant description is omitted.

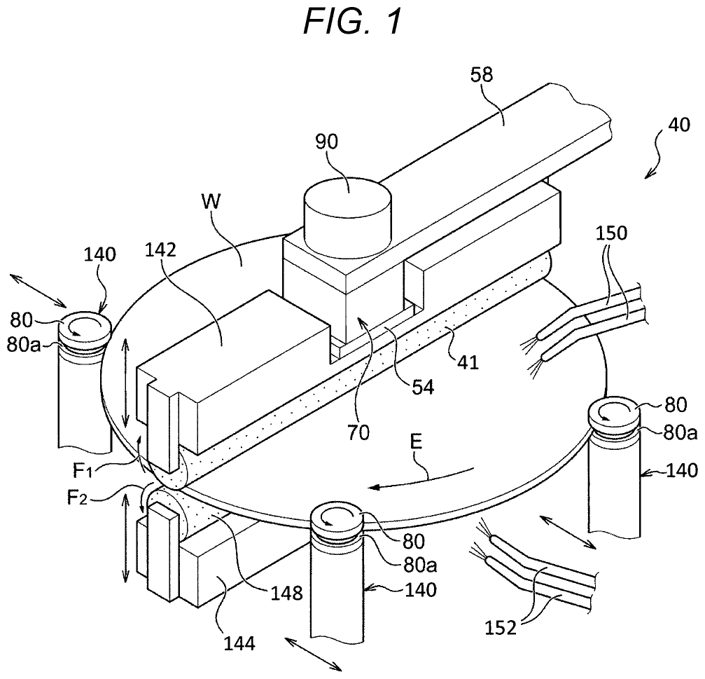

FIG. 1 is a perspective view illustrating an outline of a cleaning device 40 according to an embodiment.

As illustrated in FIG. 1, the cleaning device 40 includes a plurality of (four in the drawing) spindles 140 that horizontally rotate a substrate W while supporting a circumferential edge part of the substrate W such as a semiconductor wafer with a front surface facing upward, an upper roll arm 142 disposed above the substrate W so as to be movable upward and downward, and a lower roll arm 144 disposed below the substrate W so as to be movable upward and downward.

Here, the spindle 140 is movable in a horizontal direction as indicated by an arrow in FIG. 1. A roller 80 is provided on the spindle 140. A fitting groove 80a is formed on an outer circumferential side surface of the roller 80. The circumferential edge part of the substrate W is positioned in the fitting groove 80a, and the substrate W is rotated by pressing the roller 80 against the substrate W. As a result, the substrate W is horizontally rotated as indicated by an arrow E in FIG. 1. In the illustrated embodiment, all of the four rollers 80 are coupled to a drive mechanism (not illustrated) and apply a rotational force to the substrate W. Note that two of the four rollers 80 may apply the rotational force to the substrate W (the drive mechanism is not illustrated), and the other two rollers 80 may function as bearings that receive the rotation of the substrate W.

An upper roll cleaning member (roll sponge) 41 that is cylindrical and extends horizontally is rotatably supported by the upper roll arm 142. The upper roll cleaning member 41 is made of, for example, polyvinyl alcohol (PVA), and rotates as indicated by an arrow F1 in FIG. 1 by the drive mechanism (not illustrated). A lower roll cleaning member (roll sponge) 148 that is cylindrical and extends horizontally is rotatably supported by the lower roll arm 144. The lower roll cleaning member 148 is made of, for example, PVA, and rotates as indicated by an arrow F2 in FIG. 1 by the drive mechanism (not illustrated).

Two upper supply nozzles 150 for supplying a chemical solution and pure water (rinsing solution) to the front surface (upper surface) of the substrate W are disposed above the substrate W rotated while being supported by the spindles 140. One of the two upper supply nozzles 150 supplies the chemical solution, and the other supplies the pure water. Further, two lower supply nozzles 152 for supplying a chemical solution and pure water (rinsing solution) to a back surface (lower surface) of the substrate W are disposed below the substrate W rotated while being supported by the spindles 40. One of the two lower supply nozzles 152 supplies the chemical solution, and the other supplies the pure water. In addition, a liquid supply mechanism (not illustrated in FIG. 1) described below supplies pure water (inner rinsing solution) into each of the upper roll cleaning member 41 and the lower roll cleaning member 148. The pure water supplied into the upper roll cleaning member 41 and the lower roll cleaning member 148 is discharged from outer circumferential surfaces of the upper roll cleaning member 41 and the lower roll cleaning member 148.

The substrate W is cleaned as follows. In a state in which the substrate W is rotated horizontally, the chemical solution is supplied from the upper supply nozzle 150 to the front surface (upper surface) of the substrate W, and the upper roll cleaning member 41 is lowered while being rotated and is brought into contact with the front surface of the rotating substrate W with a predetermined pressing load. As a result, the front surface of the substrate W is scrub-cleaned by the upper roll cleaning member 41 in the presence of the chemical solution. A length of the upper roll cleaning member 41 is set to be slightly larger than a diameter of the substrate W, so that the entire front surface of the substrate W is simultaneously cleaned.

At the same time as cleaning the front surface of the substrate W, the chemical solution is supplied from the lower supply nozzle 152 to the back surface (lower surface) of the substrate W, and the lower roll cleaning member 148 is lifted while being rotated, and is brought into contact with the back surface of the rotating substrate W with a predetermined pressing load. As a result, the back surface of the substrate W is scrub-cleaned by the lower roll cleaning member 148 in the presence of the chemical solution. A length of the lower roll cleaning member 148 is set to be slightly larger than the diameter of the substrate W, so that the entire back surface of the substrate W is simultaneously cleaned. After the front surface and the back surface of the substrate W are cleaned, the pure water is supplied from the upper supply nozzle 150 and the lower supply nozzle 152 to the front surface and the back surface of the substrate W, and the pure water is supplied into each of the upper roll cleaning member 41 and the lower roll cleaning member 148, so that the substrate W, the upper roll cleaning member 41, and the lower roll cleaning member 148 are rinsed with the pure water.

Next, a configuration for supplying the pure water (inner rinsing solution) into the upper roll cleaning member 41 and the lower roll cleaning member 148 will be described in detail. A configuration of the lower roll cleaning member 148 is similar to a configuration of the upper roll cleaning member 41, and the configuration of the upper roll cleaning member 41 (which may hereinafter be simply referred to as roll cleaning member 41) will be described below as a representative.

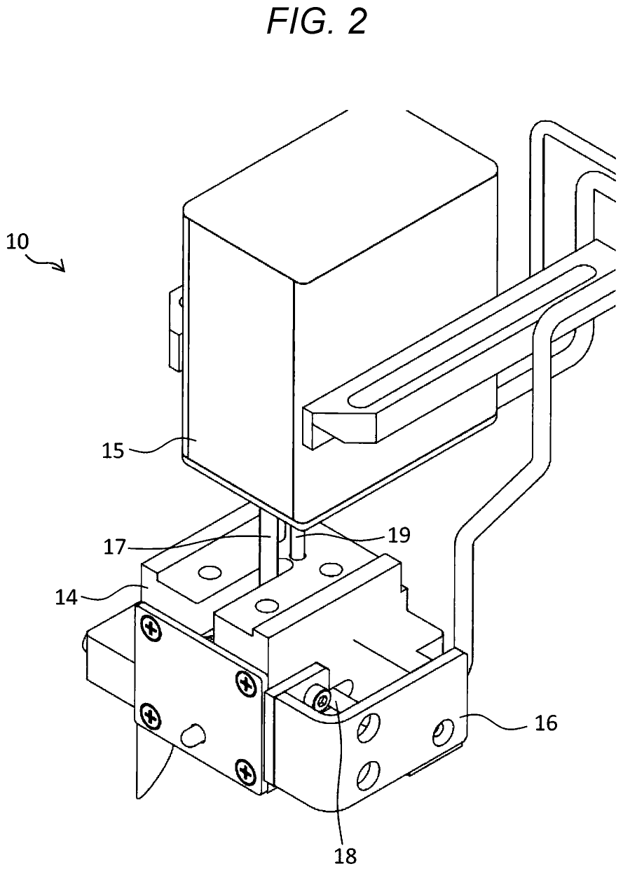

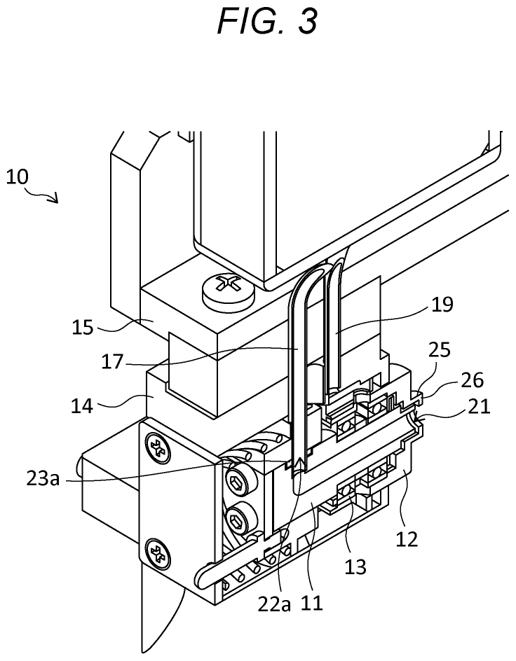

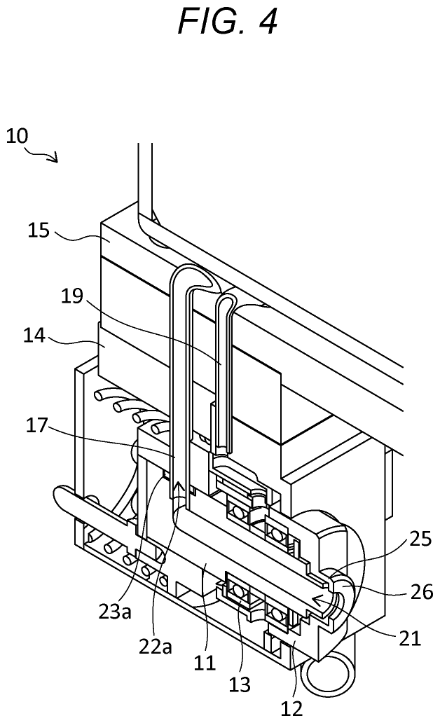

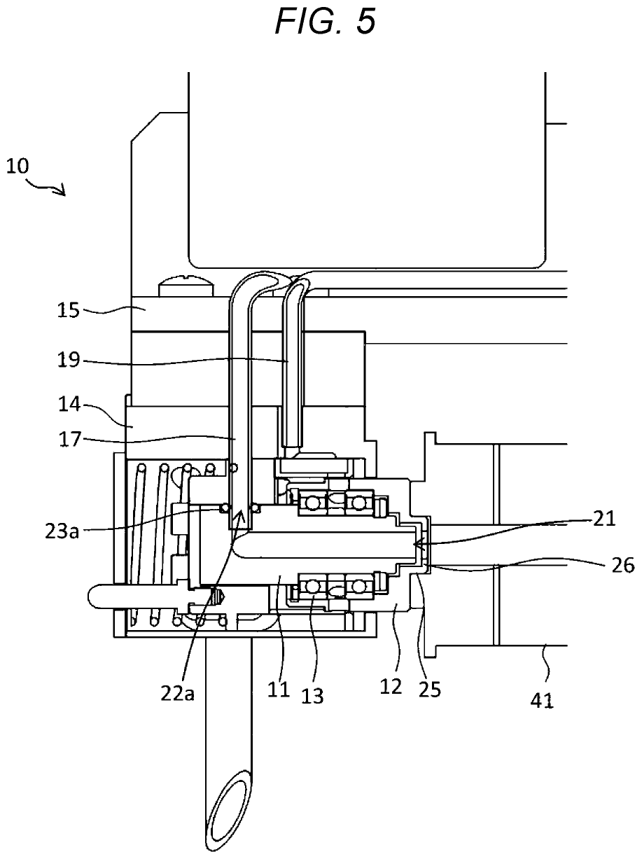

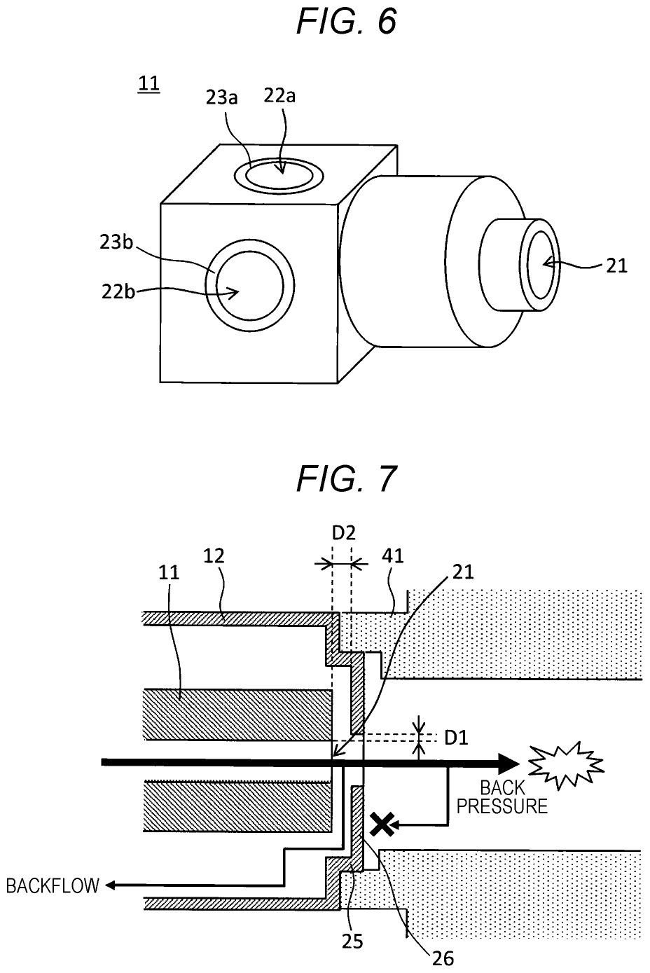

FIG. 2 is a perspective view of a support mechanism 10 for a roll cleaning member when viewed from a side opposite to the roll cleaning member 41. FIG. 3 is a perspective view of a longitudinal cross section of the support mechanism 10 for a roll cleaning member when viewed from the side opposite to the roll cleaning member 41. FIG. 4 is a perspective view of the longitudinal cross section of the support mechanism 10 for a roll cleaning member when viewed from a roll cleaning member 41 side. FIG. 5 is a view illustrating a longitudinal cross section of the support mechanism 10 for a roll cleaning member. FIG. 6 is a perspective view illustrating a configuration of a nozzle body 11.

As illustrated in FIGS. 2 to 6, the support mechanism 10 for a roll cleaning member has a housing 14, the nozzle body 11 disposed in the housing 14, a cover 12 that is engaged with the roll cleaning member 41 and rotates together with the roll cleaning member 41, and a bearing 13 housed between the nozzle body 11 and the cover 12.

The nozzle body 11 has a pipe connection port 22a to which a cleaning solution supply pipe 17 is connected, and a discharge port 21 for discharging the cleaning solution. In the illustrated example, the nozzle body 11 has a proximal end part having a substantially cubic shape and a distal end part having a lateral cylindrical shape, the pipe connection port 22a is formed on an upper surface of the proximal end part of the nozzle body 11, and the discharge port 21 is formed on an end surface of the distal end part of the nozzle body 11. A distal end of the cleaning solution supply pipe 17 is inserted downward into the pipe connection port 22a via an O-ring 23a, is positioned inside the nozzle body 11, and does not protrude to the outside from the discharge port 21. A part of the cleaning solution supply pipe 17 that extends outward from the pipe connection port 22a is clamped to the housing 14 by an upper clamp 15. The cleaning solution supplied from the cleaning solution supply pipe 17 is discharged from the discharge port 21 through the pipe connection port 22a.

As illustrated in FIGS. 2 and 6, the nozzle body 11 may further have a second pipe connection port 22b to which a second cleaning solution supply pipe 18 is connected. In the illustrated example, the second pipe connection port 22b is formed on a side surface of the proximal end part of the nozzle body 11. A distal end of the second cleaning solution supply pipe 18 is laterally inserted from the pipe connection port 22b via an O-ring 23b, is positioned inside the nozzle body 11, and does not protrude to the outside from the discharge port 21. A part of the second cleaning solution supply pipe 18 that extends outward from the second pipe connection port 22b is clamped to the housing 14 by a side clamp 16. The cleaning solution supplied from the second cleaning solution supply pipe 18 joins the cleaning solution supplied from the cleaning solution supply pipe 17 through the pipe connection port 22b and discharged from the discharge port 21. In this case, it is possible to increase a supply flow rate of the cleaning solution to the inside of the roll cleaning member 41 without increasing a pipe diameter of the cleaning solution supply pipe 17 or increasing a size of the bearing 13.

As illustrated in FIGS. 3 to 5, the cover 12 is coaxially disposed outside the distal end part of the nozzle body 11. The bearing 13 is coaxially inserted and fitted between an outer circumferential surface of the distal end part of the nozzle body 11 and an inner peripheral surface of the cover 12, and rotatably holds the cover 12 with respect to the nozzle body 11. A distal end of a bearing lubrication coolant supply pipe 19 is inserted and positioned in a part of the housing 14 that faces the bearing 11. When liquid (for example, pure water) is supplied from the bearing lubrication coolant supply pipe 19, the bearing 13 can be lubricated and/or cooled.

FIG. 7 is an enlarged view of the vicinity of the distal end part of the nozzle body 11 in the support mechanism 10 for a roll cleaning member. As illustrated in FIGS. 3 to 5 and 6, a backflow prevention wall 26 extending in the radial direction with respect to a rotation axis of the roll cleaning member 41 is provided in the cover 12.

In the illustrated example, the cover 12 has an extending part 25 extending toward the roll cleaning member 41 from the discharge port 21 of the nozzle body 11, and the backflow prevention wall 26 is provided so as to extend inward in the radial direction from the extending part 25.

Here, as a comparative example, a configuration in which a distal end of a cover 112 and a distal end of a nozzle body 111 are aligned at the same position in a direction of a rotation axis (that is, the cover 112 does not have the extending part 25), and the backflow prevention wall 26 is not provided in the cover 112 will be considered with reference to FIG. 10. In such a configuration, as illustrated in FIG. 10, when the supply flow rate of the cleaning solution is increased, a part of the cleaning solution discharged from the discharge port 21 is not supplied to the inside of the roll cleaning member 41, but is pushed back by a back pressure inside the roll cleaning member 41, and leaks to a mechanism side through a gap D0 between the nozzle body 111 and the cover 112.

In the configuration according to the comparative example, it is conceivable to decrease a size of the gap D0 between the nozzle body 111 and the cover 112 as one idea for reducing an amount of the cleaning solution leaking to the mechanism side. However, in a case where the size of the gap D0 is decreased, there is a possibility that the cover 112 and the nozzle body 111 interfere with each other during rotation of the roll cleaning member 41. Therefore, the size of the gap D0 needs to be 0.5 mm or more, and cannot be made smaller than 0.5 mm.

In the configuration according to the comparative example, it is conceivable to dispose a contact seal (for example, a mechanical seal or an oil seal) in the gap D0 between the nozzle body 111 and the cover 112 as another idea for reducing the amount of the cleaning solution leaking to the mechanism side. However, the contact seal has a problem that torque increases. Further, the roll cleaning member 41 normally rotates at a rotation speed of 100 rpm or more, but there is also a problem that there is no contact seal applicable to such a high rotation speed. Furthermore, there is also a problem that a size of the device increases.

In the configuration according to the comparative example, it is conceivable to dispose a non-contact seal (for example, an air inflow type seal or a magnetic fluid seal) in the gap D0 between the nozzle body 111 and the cover 112 as still another idea for reducing the amount of the cleaning solution leaking to the mechanism side. However, in this case, there is a problem that introduction cost increases. In addition, there is also a problem that the size of the device increases.

Therefore, with the configuration according to the comparative example, the amount of the cleaning solution leaking to the mechanism side cannot be reduced.

On the other hand, in the present embodiment, as illustrated in FIG. 7, the backflow prevention wall 26 is provided so as to extend inward in the radial direction from the extending part 25 of the cover 12, and is disposed in a direction of a flow (backflow) of the cleaning solution discharged from the discharge port 21 and pushed back by the back pressure inside the roll cleaning member 41 hinders the flow, and thus, it is possible to reduce the amount of the cleaning solution leaking to the mechanism side.

In addition, since particles generated in the bearing 13 are hindered by the backflow prevention wall 26, it is possible to prevent the particles from being mixed into the roll cleaning member 41. In addition, since the backflow prevention wall 26 is provided so as to extend inward in the radial direction from the extending part 25 of the cover 12, rigidity of the cover 12 can be improved.

Referring to FIG. 7, a radial gap D1 (hereinafter, also referred to as a first gap) between an inner circumference of the discharge port 21 and a distal end of the backflow prevention wall 26 may be smaller than a gap D2 (hereinafter, also referred to as a second gap) in a direction of the rotation axis between an end surface of the nozzle body 11 on which the discharge port 21 is formed and a side surface of the backflow prevention wall 26 when viewed in a cross section including the rotation axis. A size of the second gap D2 needs to be 0.5 mm or more so that the cover 12 and the nozzle body 11 do not interfere with each other during the rotation of the roll cleaning member 41, but a size of the first gap D1 is not restricted by the interference between the cover 12 and the nozzle body 11, and thus can be arbitrarily reduced. The first gap D1 may be smaller than the second gap D2, and may have a size of, for example, 0.4 mm or less, 0.3 mm or less, or 0.2 mm or less. Since the first gap D1 is smaller than the second gap D2, a flow rate of the cleaning solution passing through the first gap D1 can be reduced, so that the amount of the cleaning solution leaking to the mechanism side can be further reduced.

As a specific example according to the present embodiment, the inventor of the present invention measured leakage to the mechanism side at each supply flow rate while changing setting of the supply flow rate of the cleaning solution to be supplied to the nozzle body for the configuration (example) in which the backflow prevention wall 26 is provided (see FIG. 7) and the configuration (comparative example) in which the backflow prevention wall is not provided (see FIG. 10), and confirmed that a flow rate of the leakage to the mechanism side was about half in any settable flow rate range in the configuration according to the example in which the backflow prevention wall 26 is provided as compared with the configuration according to the comparative example in which the backflow prevention wall is not provided. Further, in the configuration according to the comparative example in which the backflow prevention wall is not provided, leakage of up to 13% occurred in the current flow rate range, whereas in the configuration according to the example in which the backflow prevention wall 26 is provided, it was confirmed that the leakage can be suppressed to up to 8%.

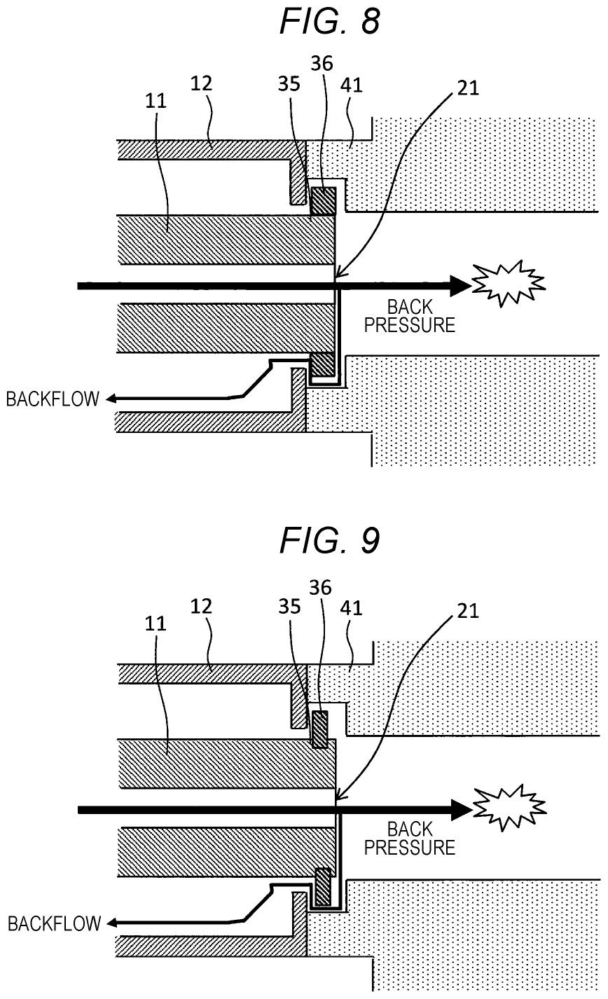

In the above-described embodiment, the backflow prevention wall 26 is provided in the cover 12, but the present invention is not limited thereto. As a modified example, as illustrated in FIG. 8, a backflow prevention wall 36 extending in the radial direction with respect to the rotation axis of the roll cleaning member 41 may be provided in the nozzle body 11. In the illustrated example, the nozzle body 11 has an extending part 35 extending toward the roll cleaning member 41 from the cover 12, and the discharge port 21 is formed at a distal end of the extending part 35. The backflow prevention wall 36 is provided so as to extend outward in the radial direction from the extending part 35 of the nozzle body 11. In this case, as illustrated in FIG. 8, the backflow prevention wall 36 that is provided in the direction of the flow (backflow) of the cleaning solution discharged from the discharge port 21 and pushed back by the back pressure inside the roll cleaning member 41 hinders the flow, and thus, it is possible to reduce the amount of the cleaning solution leaking to the mechanism side. In addition, since particles generated in the bearing 13 are hindered by the backflow prevention wall 36, it is possible to prevent the particles from being mixed into the roll cleaning member 41.

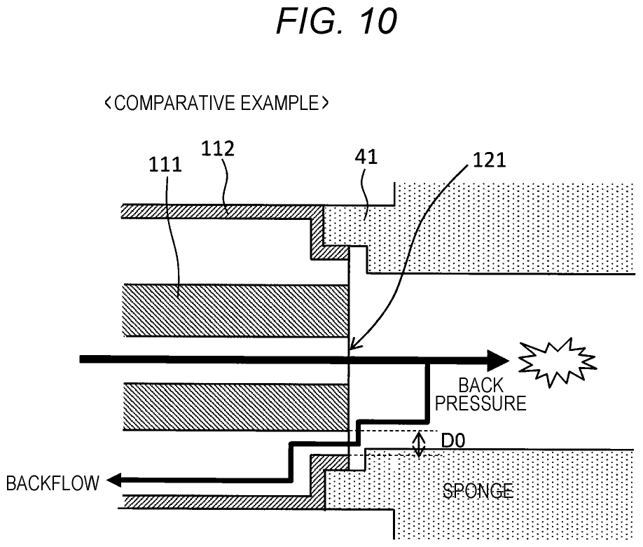

In the example illustrated in FIG. 8, the backflow prevention wall 36 is formed integrally with the extending part 36 of the nozzle body 11. However, as a second modified example, as illustrated in FIG. 9, the backflow prevention wall 36 may be formed by fitting an annular member into a groove formed on an outer circumferential surface of the extending part 36 of the nozzle body 11.

Although the embodiments and the modified examples have been described above by way of example, the scope of the present technology is not limited thereto, and can be changed and modified according to the purpose within the scope described in the claims. In addition, the embodiments and the modified examples can be appropriately combined within a range in which the processing contents do not contradict each other.

1. A support mechanism for a roll cleaning member, the support mechanism comprising:
a nozzle body that has a pipe connection port to which a cleaning solution supply pipe is connected and a discharge port from which a cleaning solution is discharged;
a cover that is engaged with the roll cleaning member and rotates together with the roll cleaning member; and
a bearing that is housed between the nozzle body and the cover,
wherein a backflow prevention wall extending in a radial direction with respect to a rotation axis of the roll cleaning member is provided in at least one of the nozzle body and the cover.

2. The support mechanism according to claim 1, wherein
the cover has an extending part extending toward the roll cleaning member from the discharge port of the nozzle body, and
the backflow prevention wall is provided so as to extend inward in the radial direction from the extending part.

3. The support mechanism according to claim 2, wherein
a gap in the radial direction between an inner circumference of the discharge port and a distal end of the backflow prevention wall is smaller than a gap in a direction of the rotation axis between an end surface of the nozzle body on which the discharge port is formed and a side surface of the backflow prevention wall when viewed in a cross section including the rotation axis.

4. The support mechanism according to claim 1, wherein
the nozzle body has an extending part extending toward the roll cleaning member from the cover, the discharge port is formed at a distal end of the extending part, and
the backflow prevention wall is provided so as to extend outward in the radial direction from the extending part.

5. The support mechanism according to claim 1, wherein
the nozzle body further has a second pipe connection port to which a second cleaning solution supply pipe is connected.

6. A cleaning device comprising:
a roll cleaning member; and
the support mechanism according to claim 1.

7. The cleaning device according to claim 6, wherein
the cover has an extending part extending toward the roll cleaning member from the discharge port of the nozzle body, and
the backflow prevention wall is provided so as to extend inward in the radial direction from the extending part.

8. The cleaning device according to claim 7, wherein
a gap in the radial direction between an inner circumference of the discharge port and a distal end of the backflow prevention wall is smaller than a gap in a direction of the rotation axis between an end surface of the nozzle body on which the discharge port is formed and a side surface of the backflow prevention wall when viewed in a cross section including the rotation axis.

9. The cleaning device according to claim 6, wherein
the nozzle body has an extending part extending toward the roll cleaning member from the cover, the discharge port is formed at a distal end of the extending part, and
the backflow prevention wall is provided so as to extend outward in the radial direction from the extending part.

10. The cleaning device according to claim 6, wherein
the nozzle body further has a second pipe connection port to which a second cleaning solution supply pipe is connected.
